(19) United States
(12) Patent Application Publication
(10) Pub. No.: US 2009/0078989 A1
(43) Pub. Date: Mar. 26, 2009

(54) Method of forming silicon nitride at low temperature, charge trap memory device including crystalline nano dots formed by using the same, and method of manufacturing the charge trap memory device

(75) Inventors: Kwang-soo Seol, Yongin-si (KR); Nong-moon Hwang, Seoul (KR); Chan-soo Kim, Seoul (KR); Dong-kwon Lee, Seoul (KR); Woong-kyu Youn, Incheon (KR); Sang-moo Choi, Yongin-si (KR)

Correspondence Address: HARNESS, DICKEY & PIERCE, P.L.C., P.O. BOX 8910, RESTON, VA, 20195, US

(73) Assignees: Samsung Electronics Co., Ltd.; Seoul National University Industry Foundation

(21) Appl. No.: 12/213,329

(22) Filed: Jun. 18, 2008

(30) Foreign Application Priority Data
Sep. 21, 2007 (KR) 10-2007-0096963
Apr. 30, 2008 (KR) 10-2008-0040821

(51) Int. Cl. H01L 21/28; H01L 21/318; H01L 29/792

(52) U.S. Cl. 257/324; 438/791; 438/591; 257/E21.293; 257/E29.309; 257/E21.21

(57) ABSTRACT

Provided are a method of forming silicon nitride at a low temperature, a charge trap memory device including crystalline nano dots formed by using the same, and a method of manufacturing the charge trap memory device. The method of forming silicon nitride includes loading a substrate into a chamber of a silicon nitride deposition device comprising a filament; increasing a temperature of the filament to a temperature whereby a reactant gas to be injected into the chamber may be dissociated; and injecting the reactant gas into the chamber so as to form a crystalline silicon nitride film or crystalline silicon nitride nano dots on the substrate. In the method, the temperature of the filament may be maintained at 1,400° C.˜2,000° C., and a pressure in the chamber may be maintained at several to several ten torr when the reactant gas in injected into the chamber.

### CROSS-REFERENCE TO RELATED PATENT APPLICATION

This application claims the benefit of Korean Patent Application No. 10-2007-0096963, filed on Sep. 21, 2007, and Korean Patent Application No. 10-2008-0040821, filed on Apr. 30, 2008, in the Korean Intellectual Property Office, the disclosures of which are incorporated herein in their entirety by reference.

### BACKGROUND OF THE INVENTION

1. Field of the Invention

The present invention relates to a method of forming silicon nitride at a low temperature, a charge trap memory device including crystalline nano dots formed by using the same, and a method of manufacturing the charge trap memory device.

2. Description of the Related Art

A silicon nitride film has a high dielectric constant and excellent oxidation-resistance. Accordingly, the silicon nitride film may be applied to a microelectronic device and used as, for example, a barrier layer or a gate insulating layer.

If a crystalline silicon nitride film is used as a gate insulating layer, the permittivity of a gate is increased and impurities included in a raw material used in forming the gate are prevented from being diffused to a substrate.

A silicon nitride film is formed on a silicon (100) substrate. The silicon nitride film is formed by using a plasma-enhanced chemical vapor deposition (CVD) method or a low-pressure CVD method.

However, the silicon nitride film formed by using the plasma-enhanced CVD method or the low-pressure CVD method is amorphous. A thick amorphous silicon nitride film has an acceptably low leakage current. However, a thin amorphous silicon nitride film having a thickness of, for example, less than 500 may have a large leakage current.

Meanwhile, if a doped poly silicon gate is disposed on the (100) surface of the silicon substrate and a silicon dioxide (SiO₂) film is disposed between the doped poly silicon gate and the silicon substrate as a gate insulating film, a doping material such as boron may be diffused from the doped poly silicon gate to the silicon substrate through the SiO₂ film. Such diffusion increases as a thickness of the gate insulating film is decreased. Thus, characteristics of a semiconductor device may deteriorate in a channel region.

On the other hand, if an amorphous silicon nitride film is used as the gate insulating film, the doping material is prevented from being diffused to the silicon substrate. However, due to the amorphous silicon nitride film between the doped poly silicon gate and the silicon substrate, an electronic current may be blocked in a channel of an active semiconductor device. Thus, characteristics of the semiconductor device may further deteriorate in comparison with a case where a SiO₂ film is used as the gate insulating film.

Meanwhile, if a SiO₂ film is used as the gate insulating film and the SiO₂ film is thin, due to an electron tunneling phenomenon occurring between a gate and a drain of a transistor, a leakage current increases to an unacceptable level. Thus, it is difficult to decrease the thickness of the SiO₂ film.

However, a silicon nitride film has a larger bulk dielectric constant than a SiO₂ film and thus a thick silicon nitride film has the same electrostatic capacity density as that of a thin SiO₂ film.

However, as described above, a silicon nitride film formed by using a conventional method is amorphous and if the silicon nitride film is thin, a leakage current may increase.

### SUMMARY OF THE INVENTION

The present invention provides a method of forming silicon nitride at a low temperature by which an electronic current may not be blocked in a channel of an active semiconductor device, a leakage current may not increase even when the silicon nitride is thin, and a crystalline silicon nitride film or nano dots may be formed on a substrate at a low temperature, which is not possible using a conventional method.

The present invention also provides a charge trap memory device including crystalline nano dots formed by using the above method, and a method of manufacturing the charge trap memory device.

According to an aspect of the present invention, there is provided a method of forming crystalline silicon nitride, the method including loading a substrate into a chamber of a silicon nitride deposition device comprising a filament; increasing a temperature of the filament to a temperature whereby a reactant gas to be injected into the chamber may be dissociated; and injecting the reactant gas into the chamber so as to form crystalline silicon nitride on the substrate, wherein the temperature of the filament is maintained at 1,400° C.—2,000° C., and wherein a pressure in the chamber is maintained at several to several ten torr when the reactant gas in injected into the chamber.

The substrate may be maintained at 500° C.˜700° C.

The pressure in the chamber may be maintained at four through forty torr.

The reactant gas may include a first source gas for providing silicon (Si) and a second source gas for providing nitrogen (N), and the first source gas may be monosilane (SiH₄), disilane (Si₂H₆), trisilane (Si₃H₈), or tetrasilane (Si₄H₁₀).

If the first source gas is 20% of SiH₄ and the second source gas is ammonia (NH₃), a flow ratio of 20% of SiH₄ to NH₃ may be maintained at 1:50, 1:100, or 1:200.

According to another aspect of the present invention, there is provided a charge trap memory device including a tunnelling film, a charge trap layer, a charge blocking layer, and a gate electrode, which are sequentially stacked on a substrate, wherein the charge trap layer is formed of crystalline silicon nitride.

The charge trap layer may be a crystalline silicon nitride nano dot layer.

The crystalline silicon nitride nano dot layer may be polycrystalline.

The tunnelling film may be amorphous.

According to another aspect of the present invention, there is provided a method of manufacturing a charge trap memory device including a gate stack including a charge trap component, the method including forming a tunnelling film on a substrate; forming crystalline silicon nitride on the tunnelling film, as the charge trap component; forming a charge blocking layer covering the crystalline silicon nitride; and forming a gate electrode on the charge blocking layer.

The crystalline silicon nitride may be formed by using a hot wire chemical vapor deposition (HWCVD) device. In this case, the crystalline silicon nitride may be formed by using the above-described method of forming crystalline silicon nitride.

The crystalline silicon nitride may be crystalline silicon nitride nano dots.

The crystalline silicon nitride nano dots may be polycrystalline.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a film deposition device that is used in a method of forming a crystalline silicon nitride film at a low temperature, according to an embodiment of the present invention;

FIG. 2 is a flowchart of a method of forming a crystalline silicon nitride film at a low temperature by using the film deposition device illustrated in FIG. 1, according to an embodiment of the present invention;

FIGS. 3 and 4 are graphs respectively illustrating results of first and second experiments performed in order to calculate variations of a composition ratio of a crystalline silicon nitride film in accordance with variations in temperature of a filament as a reaction pressure in a chamber varies, according to embodiments of the present invention;

FIGS. 5 and 6 are high resolution transmission electron microscopy (HRTEM) images respectively illustrating results of third and fourth experiments performed in order to find out the influence of variations in temperature of a filament on a crystalline silicon nitride film, when the crystalline silicon nitride film is formed by using the film deposition device illustrated in FIG. 1, according to embodiments of the present invention;

FIG. 7 is a HRTEM image illustrating a result of a fifth experiment performed by increasing a pressure from four torr to forty torr under the same conditions as those of the fourth experiment illustrated in FIG. 6, according to an embodiment of the present invention;

FIG. 8 is a cross sectional view of a charge trap memory device including crystalline silicon nitride nano dots, according to an embodiment of the present invention;

FIGS. 9 through 11 are diagrams for describing a method of manufacturing the charge trap memory device illustrated in FIG. 8, according to an embodiment of the present invention;

FIG. 12 is a transmission electron microscopy (TEM) image illustrating a nano dot layer illustrated in FIGS. 9 through 11 when the nano dot layer is a crystalline silicon nitride nano dot layer, according to an embodiment of the present invention; and

FIGS. 13 and 14 are magnified images of portions of the image of FIG. 12.

### DETAILED DESCRIPTION OF THE INVENTION

Hereinafter, the present invention will be described in detail by explaining embodiments of the invention with reference to the attached drawings. In the drawings, the thicknesses of layers and regions are exaggerated for clarity. The invention may be embodied in many different forms and should not be construed as being limited to the embodiments set forth herein.

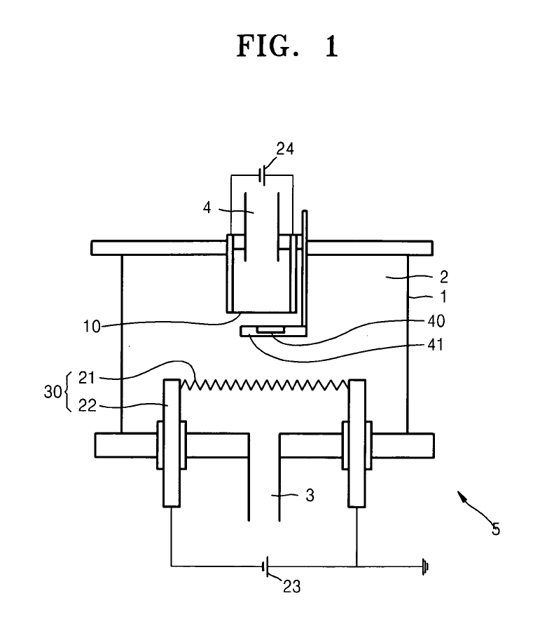

FIG. 1 is a cross-sectional view of a film deposition device 5 that is used in a method of forming a crystalline silicon nitride film at a low temperature, according to an embodiment of the present invention. The film deposition device 5 is a hot wire chemical vapor deposition (HWCVD) device.

Referring to FIG. 1, the film deposition device 5 includes a chamber 1, a gas inlet 3, a gas outlet 4, and a filament 21. A raw gas such as a reactant gas or an atmospheric gas is injected into the chamber 1 through the gas inlet 3. If the crystalline silicon nitride film is formed in the chamber 1, the reactant gas may be 20% of silane (SiH₄) and ammonia (NH₃). The atmospheric gas may be hydrogen (H₂). The raw gas is exhausted outside the chamber 1 through the gas outlet 4. The filament 21 emits heat for dissociating the reactant gas injected into the chamber 1. In this case, the filament 21 may be maintained at a predetermined temperature. For example, when the reactant gas is injected into the chamber 1 in order to form the crystalline silicon nitride film, the filament 21 may be maintained at 1,400° C.˜2,000° C., and more preferably, at 1,700° C. The filament 21 used to dissociate the reactant gas at a high temperature may be formed of a single metal such as tungsten (W) coated by graphite. However, the filament 21 may also be formed of a metallic alloy heating element comprising materials such as molybdenum (Mo), platinum (Pt), tantalum (Ta), and iridium (Ir). The filament 21 may be a single wire, a twisted wire, or another type of wire. Furthermore, the filament 21 may include one or more filaments.

The film deposition device 5 further includes electrodes 22, a substrate holder 41 holding a substrate 40 while the crystalline silicon nitride film is being formed, a heater 10, and voltage sources 23 and 24. A voltage is supplied from the voltage source 23 to the filament 21 through the electrodes 22. The filament 21 and the electrodes 22 are integrally referred to as a hot wire 30. A thin film or nano dots may be formed on a surface of the substrate 40. For example, a crystalline silicon nitride layer or crystalline silicon nitride nano dots may be formed on a surface of the substrate 40, which will be described in detail later. The substrate holder 41 may hold various sizes of the substrate 40. The heater 10 maintains the substrate 40 at a predetermined temperature while the thin film is being formed. For example, the heater 10 maintains the substrate 40 at 500° C.˜700° C. while the crystalline silicon nitride film is being formed. The voltage source 24 supplies a voltage to the heater 10. Here, a fixed alternating or direct voltage may be supplied by the voltage source 24.

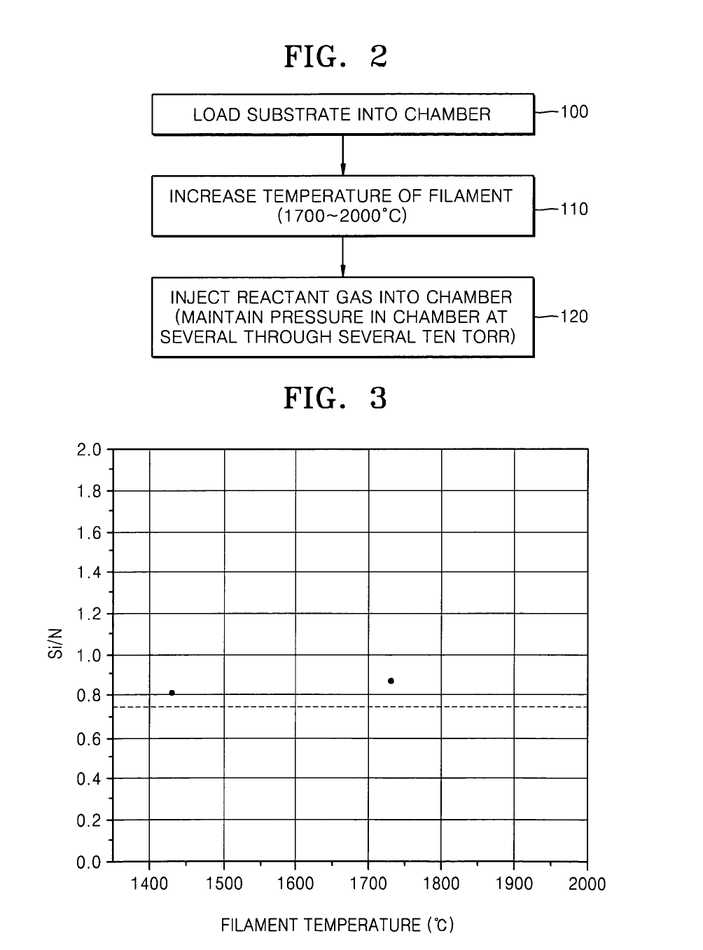

FIG. 2 is a flowchart of a method of forming a crystalline silicon nitride film at a low temperature by using the film deposition device 5 illustrated in FIG. 1, according to an embodiment of the present invention. FIG. 2 will be described in conjunction with FIG. 1.

Referring to FIG. 2, firstly, the substrate 40 is loaded into the chamber 1 in operation 100. In this case, a pressure in the chamber 1 may be maintained at several ten mtorr, for example, 10⁻² torr. The substrate 10 may be a silicon (100) substrate. Then, H₂ may be injected into the chamber 1 as an atmospheric gas so as to prevent the filament 21 from being oxidized. A predetermined distance that is appropriate to form a crystalline silicon nitride layer or crystalline silicon nitride nano dots on the substrate 40, may be maintained between the substrate 40 and the filament 21. For example, the distance between the substrate 40 and the filament 21 may be approximately 6.5 cm. If other conditions are fixed, a crystalline silicon nitride layer or crystalline silicon nitride nano dots may be formed on the substrate 40 by controlling the distance between the substrate 40 and the filament 21. Then, a temperature of the filament 21 is increased high enough to dissociate a reactant gas to be injected into the chamber 1 in operation 110. For example, when the reactant gas is injected into the chamber 1 in order to form a silicon nitride film or nano dots, the temperature of the filament 21 may be increased to 1,400° C.˜2,000° C., and more preferably, to 1,700° C.

Then, the reactant gas is injected into the chamber 1 through the gas inlet 3 in operation 120. The reactant gas may be a source gas required to form the silicon nitride film or the nano dots. In this case, the pressure in the chamber 1 may be maintained at several to several ten torr and the substrate 10 may be maintained at 500° C.˜700° C. For example, the pressure in the chamber 1 may be maintained at four through forty torr.

The source gas may include monosilane (SiH₄), disilane (Si₂H₆), trisilane (Si₃H₈), or tetrasilane (Si₄H₁₀) for providing silicon (Si), and may further include NH₃ for providing nitrogen (N). Here, the flow rate of the source gas is maintained so that a ratio of 20% of SiH₄ to NH₃ is 1:50, 1:100, or 1:200. In this case, the flow rate of NH₃ may be maintained at two hundred sccm.

The injected reactant gas is dissociated by passing through the filament 21. The dissociated reactant gas is condensed in a vapor phase so as to form a seed of silicon nitride, and then a crystalline nanoparticle may be formed from the seed.

Meanwhile, due to the pressure condition in the chamber 1, the supersaturation degree of the injected reactant gas is lowered. When the supersaturation degree is lowered, the injected reactant gas is not dissociated in a region of a low temperature, for example, lower than 1,700° C., around the filament 21. Also, the seed is not formed from the reactant gas.

The formed nanoparticle is deposited on the substrate 40 so as to form the crystalline silicon nitride film. In this case, a deposition time may be approximately 30 minutes. However, the deposition time is not limited to 30 minutes. The deposition time may be shorter than 30 minutes, for example, several seconds. Since the crystalline silicon nitride film is formed as a result of sufficiently forming particles of crystalline silicon nitride nano dots on the substrate 40, the crystalline silicon nitride nano dots may also be formed on the substrate 40 by controlling the deposition time.

A description of a nanoparticle formed by using a HWCVD method and a thin film formed by the nanoparticle is given in ‘N. M. Hwang, I. D. Jeon and D. Y. Kim, and J. Ceram. Process. Res., 1, 33 (2000)’.

Hereinafter, results of experiments using the method of forming a crystalline silicon nitride film, which have been performed by the present inventor, will now be described.

Initially, the present inventor performed first and second experiments in order to calculate variations of a composition ratio of silicon nitride in accordance with variations in temperature of a filament as a reaction pressure in a chamber varies.

The first experiment was performed in accordance with the method described above with reference to FIG. 2. Here, 20% of SiH₄ and NH₃ were used as a reactant gas. A crystalline silicon nitride film was formed by maintaining a ratio of SiH₄ (20%) to NH₃ at 1:200, a pressure in the chamber at four torr, and a temperature of a substrate at 700° C.

The second experiment has been performed by increasing the pressure in the chamber from four torr to forty torr under the same conditions as those of the first experiment.

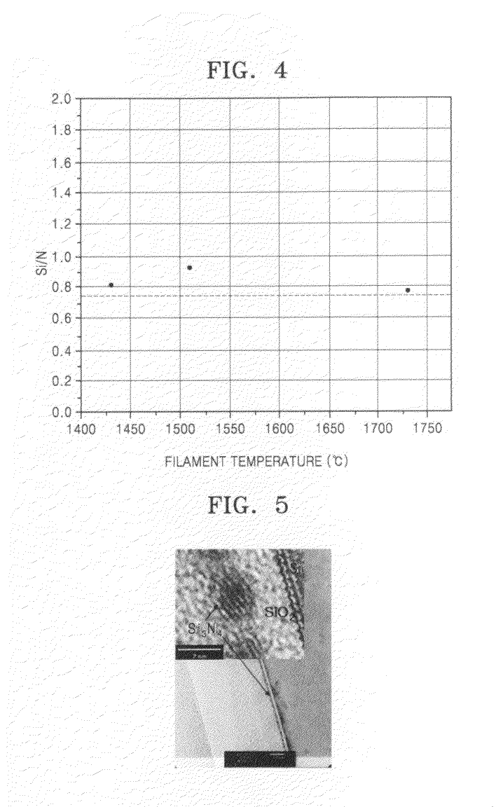

FIGS. 3 and 4 are graphs respectively illustrating results of x-ray diffraction analyses of the first and second experiments, according to embodiments of the present invention.

Referring to FIGS. 3 and 4, as the reaction pressure in the chamber varies, the composition ratio of silicon nitride varies in accordance with variations in the temperature of the filament.

Then, the present inventor performed third and fourth experiments in order to find out the influence of variations in temperature of a filament when a pressure in a chamber is constantly maintained.

In the third experiment, 20% of SiH₄ was used at a flow rate of five sccm and NH₃ was used at a flow rate of two hundred sccm. A flow ratio was maintained at 1:200. Crystalline silicon nitride such as Si₃N₄ was formed by maintaining the temperature of the filament at 1,430° C., a temperature of a substrate at 700° C., and a pressure in the chamber at four torr.

The fourth experiment was performed by maintaining the temperature of the filament at 1,730° C. under the same conditions as those of the third experiment.

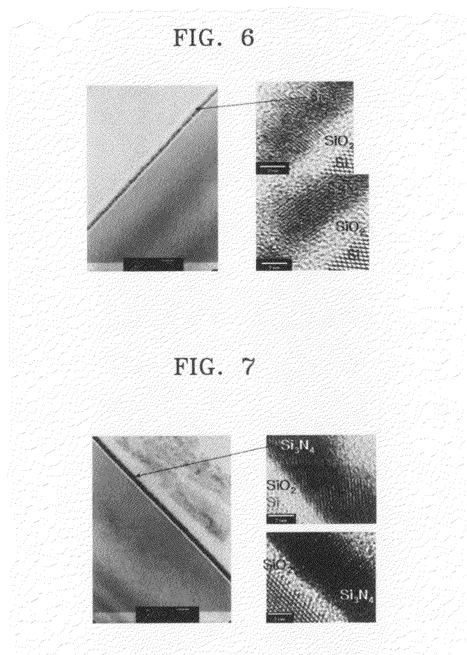

FIGS. 5 and 6 are high resolution transmission electron microscopy (HRTEM) images respectively illustrating results of the third and fourth experiments, according to embodiments of the present invention.

Referring to FIGS. 5 and 6, it is clear that silicon nitride such as Si₃N₄ formed in the third and fourth experiments are crystalline and the size and density of crystalline particles and the thickness of the silicon nitride formed in the third experiment are different from those of the silicon nitride formed in the fourth experiment.

Based on such results of the third and fourth experiments, it is clear that variations in temperature of a filament influence a size and density of crystalline particles and a thickness of silicon nitride.

Then, a fifth experiment was performed so as to form silicon nitride by increasing a pressure in a chamber from four torr to forty torr under the same conditions as those of the fourth experiment.

FIG. 7 is a HRTEM image illustrating silicon nitride formed by performing the fifth experiment, according to an embodiment of the present invention.

Referring to FIG. 7, it is clear that the silicon nitride such as Si₃N₄ formed by performing the fifth experiment is also crystalline. Furthermore, it is clear that crystals of the silicon nitride formed on regions where a native oxide film of a substrate is thin are formed in the same direction as the direction of the crystals of a silicon wafer that is used as the substrate.

Based on such results of FIG.7, silicon nitride may be directly formed on a silicon substrate from which a native oxide film is removed so that crystals of the silicon nitride are formed in the same direction as the direction of the crystals of the substrate. Accordingly, if the silicone substrate is monocrystalline, monocrystalline silicon nitride may be formed.

Referring to FIGS. 6 and 7, under the same conditions, if the pressure in the chamber is increased, the density of the crystalline particles is increased and a crystalline region having crystallographically the same directions is also increased.

Meanwhile, a temperature of the substrate is maintained at 700° C. in FIGS. 5 through 7. Generally, in this temperature condition, when atoms or molecules in a vapor phase reach the substrate and are formed into the silicon nitride, a crystalline phase may not be formed.

However, by using the method illustrated in FIG. 2, the crystalline particles are formed on the silicon nitride formed on the substrate at 700° C. These crystalline particles are not formed by the atoms or molecules reaching the substrate, but are formed by crystalline nanoparticles formed by a dissociated reactant gas in a vapor phase.

Although amounts of crystalline particles may differ in accordance with conditions of tests as illustrated in FIGS. 5 through 7, a crystalline silicon nitride film or nano dots may be formed on a substrate at a low temperature, which is not possible using a conventional method.

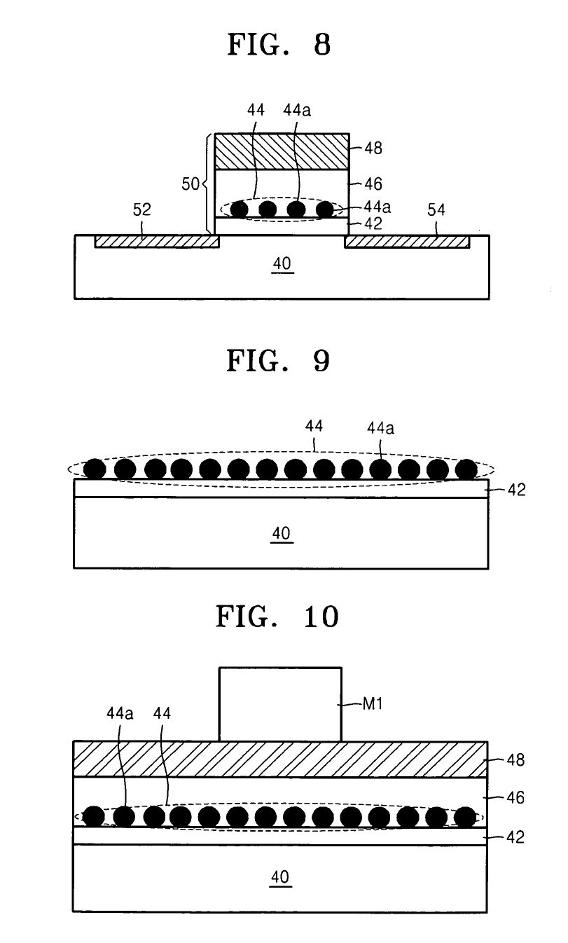

FIG. 8 is a cross sectional view of a charge trap memory device including crystalline silicon nitride nano dots, according to an embodiment of the present invention.

Referring to FIG. 8, the charge trap memory device according to the current embodiment of the present invention includes a gate stack 50 on a substrate 40. First and second impurity regions 52 and 54 are separately disposed on both sides of the substrate 40 where the gate stack 50 is not disposed. One of the first and second impurity regions 52 and 54 is a source region and the other is a drain region. The gate stack 50 includes a tunnelling film 42, a nano dot layer 44, a charge blocking layer 46, and a gate electrode 48, which are sequentially stacked. The tunnelling film 42 may be, for example, a silicone oxide film. In this case, the silicone oxide film may be amorphous. The nano dot layer 44 is a charge trap layer and includes a plurality of nano dots 44a. The nano dots 44a may be formed of crystalline silicon nitride and may be, for example, crystalline Si₃N₄ nano dots. The nano dots 44a are covered by the charge blocking layer 46. The charge blocking layer 46 prevents a charge trapped in the nano dot layer 44 from being leaked to the gate electrode 48.

As described above, the charge trap memory device illustrated in FIG. 8 includes the nano dot layer 44 formed of the crystalline silicon nitride, as a charge trap layer. Accordingly, due to an advantage of the crystalline silicon nitride, shallow defects may be reduced and thus an excellent ETA effect may be achieved. Also, due to an advantage of nano dots, a lateral migration effect may be reduced.

FIGS. 9 through 11 are diagrams for describing a method of manufacturing the charge trap memory device illustrated in FIG. 8, according to an embodiment of the present invention.

Referring to FIG. 9, a tunnelling film 42 is formed on a substrate 40. The tunnelling film 42 may be an amorphous silicone oxide film such as an amorphous SiO₂ film. The tunnelling film 42 may be formed of another material that is appropriate to form a nano dot layer 44 to be described later. After the tunnelling film 42 is formed, the substrate 40 is loaded into a HWCVD device that is described above as the film deposition device 5 illustrated in FIG. 1, and is held by a substrate holder 41. Then, the HWCVD device operates in accordance with the above-mentioned conditions so as to form the nano dot layer 44, which is crystalline, on the tunnelling film 42 that is formed on the substrate 40. Various conditions for forming the nano dot layer 44 are described above when the HWCVD device is described, and thus descriptions of the conditions will be omitted here. The nano dot layer 44 includes a plurality of nano dots 44a. The nano dots 44a may be formed of, for example, crystalline silicon nitride. If the tunnelling film 42 is an amorphous silicon oxide film, the crystalline phase of the nano dots 44a may be a polycrystalline phase. If the nano dot layer 44 is a crystalline silicon nitride nano dot layer, an example of a deposition condition of the crystalline silicon nitride nano dot layer is as described below. However, the crystalline silicon nitride nano dot layer may also be formed under any other condition from among the above-described conditions.

Filament Temperature: 1730° C., Reaction Pressure (Pressure in HWCVD Device): 40 torr, Gas Supply Ratio: NH₃/SiH₄=200, Temperature of Substrate 40: 700° C.

After the nano dot layer 44 is formed on the tunnelling film 42, the substrate 40 is took out from the HWCVD device and is loaded into a film deposition device that is used when the tunnelling film 42 is formed, or another device that is similar to the film deposition device, in order to perform the following operations.

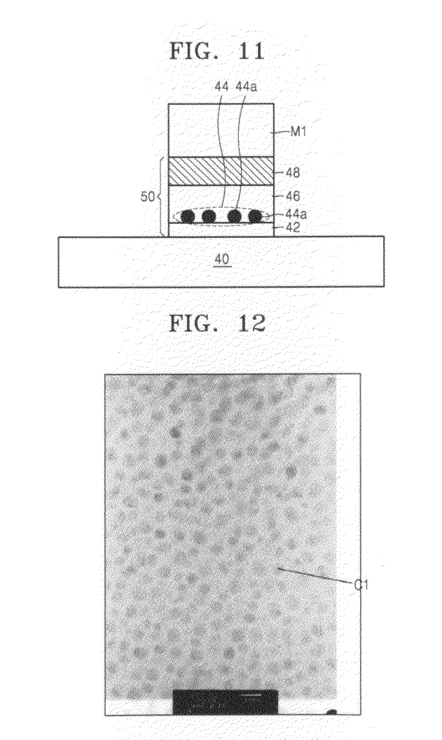

Referring to FIG. 10, a charge blocking layer 46 is formed on the tunnelling film 42 so as to cover the nano dot layer 44. The charge blocking layer 46 may be an insulating material film that may prevent a charge trapped in the nano dot layer 44 from being leaked to a gate electrode 48, and may also prevent charges from flowing from the gate electrode 48 into the nano dot layer 44. For example, the charge blocking layer 46 may be an aluminium oxide film. The gate electrode 48 is formed on the charge blocking layer 46. The gate electrode 48 may be a doped silicon layer, a metal layer, a conductive alloy layer, or a conductive oxide layer. A mask M1 is formed on the gate electrode 48. The mask M1 defines a region where the gate electrode 48 is formed. The gate electrode 48, the charge blocking layer 46, the nano dot layer 44, and the tunnelling film 42 around the mask M1 are sequentially etched. Etching is performed until the substrate 40 is exposed. As a result of the etching, a gate stack 50 is formed on the substrate 40 as illustrated in FIG. 11. Then, the mask M1 is removed. After the mask M1 is removed, the first and second impurity regions 52 and 54 illustrated in FIG. 8 may be formed on the substrate 40 through a conventional process so as to form source and drain regions. Here, gate spacers (not shown) covering the side walls of the gate stack 50 may further be formed, and the first and second impurity regions 52 and 54 may be formed so as to have a lightly doped drain (LDD) structure.

FIG. 12 is a transmission electron microscopy (TEM) image illustrating the nano dot layer 44 illustrated in FIGS. 9 through 11 when the nano dot layer 44 is a crystalline silicon nitride nano dot layer, according to an embodiment of the present invention.

Referring to FIG. 12, a plurality of circular objects C1 are observed on the image. The circular objects Cl are the nano dots 44a illustrated in FIGS. 9 through 11.

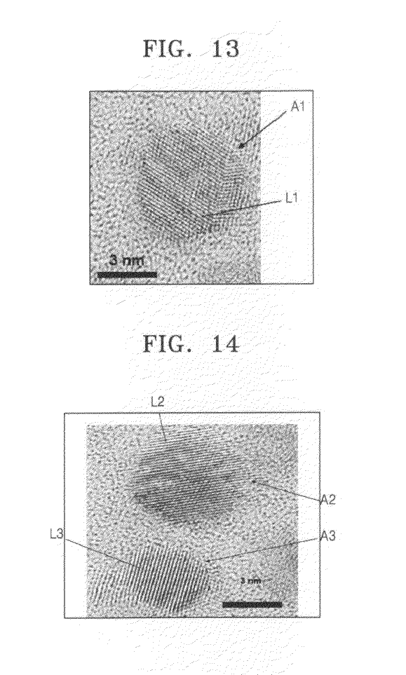

FIGS. 13 and 14 are magnified images of portions of the image of FIG. 12. A first region A1 illustrated in FIG. 13 and second and third regions A2 and A3 illustrated in FIG. 14 indicate the nano dots 44a illustrated in FIGS. 9 through 11.

Referring to FIGS. 13 and 14, the first through third regions A1 through A3 respectively include first through third parallel line groups L1 through L3 and thus are clearly identified from neighboring regions not including parallel line groups. Each of the first through third parallel line groups L1 through L3 indicates a crystal surface, which means that the phase of the nano dots 44a is a crystalline phase.

As described above, according to the above embodiments of the present invention, crystalline nanoparticles formed in a vapor phase are deposited on a substrate and thus a crystalline silicon nitride film or nano dots may be formed on the substrate at a low temperature, which is not possible using a conventional method. Therefore, impurities included in a raw material used in forming a gate are prevented from being diffused to the substrate and a leakage current occurring due to amorphous silicon nitride may be reduced.

While the present invention has been particularly shown and described with reference to exemplary embodiments thereof, the exemplary embodiments should be considered in a descriptive sense only and not for purposes of limitation. For example, when a method of forming a crystalline silicon nitride film or crystalline silicon nitride nano dots, according to an embodiment of the present invention, is performed, those of ordinary skill in the art may make small changes in operation conditions in a chamber. Also, the method may be applied to various methods of manufacturing a semiconductor device in which a silicon nitride film or crystalline silicon nitride nano dots may be used. Therefore, the scope of the invention is defined not by the detailed description of the invention but by the appended claims, and all differences within the scope will be construed as being included in the present invention.

What is claimed is:

1. A method of forming crystalline silicon nitride, the method comprising:
loading a substrate into a chamber of a silicon nitride deposition device comprising a filament;
increasing a temperature of the filament to a temperature whereby a reactant gas to be injected into the chamber may be dissociated; and
injecting the reactant gas into the chamber so as to form crystalline silicon nitride on the substrate,
wherein the temperature of the filament is maintained at 1,400° C.˜2,000° C., and
wherein a pressure in the chamber is maintained at several to several ten torr when the reactant gas in injected into the chamber.

2. The method of claim 1, wherein the substrate is maintained at 500° C.˜700° C.

3. The method of claim 1, wherein the pressure in the chamber is maintained at four through forty torr.

4. The method of claim 1, wherein the reactant gas comprises a first source gas for providing silicon (Si) and a second source gas for providing nitrogen (N), and
wherein the first source gas is monosilane (SiH₄), disilane (Si₂H₆), trisilane (Si₃H₈), or tetrasilane (Si₄H₁₀).

5. The method of claim 4, wherein, if the first source gas is 20% of SiH₄ and the second source gas is ammonia (NH₃), a flow ratio of 20% of SiH₄ to NH₃ is maintained at 1:50, 1:100, or 1:200.

6. A charge trap memory device comprising a tunnelling film, a charge trap layer, a charge blocking layer, and a gate electrode, which are sequentially stacked on a substrate, wherein the charge trap layer is formed of crystalline silicon nitride.

7. The charge trap memory device of claim 6, wherein the charge trap layer is a crystalline silicon nitride nano dot layer.

8. The charge trap memory device of claim 7, wherein the crystalline silicon nitride nano dot layer is polycrystalline.

9. The charge trap memory device of claim 6, wherein the tunnelling film is amorphous.

10. A method of manufacturing a charge trap memory device comprising a gate stack comprising a charge trap component, the method comprising:
forming a tunnelling film on a substrate;
forming crystalline silicon nitride on the tunnelling film, as the charge trap component;
forming a charge blocking layer covering the crystalline silicon nitride; and
forming a gate electrode on the charge blocking layer.

11. The method of claim 10, wherein the crystalline silicon nitride is formed by using a hot wire chemical vapor deposition (HWCVD) device.

12. The method of claim 11, wherein the crystalline silicon nitride is formed by using the method of claim 1.

13. The method of claim 10, wherein the crystalline silicon nitride is crystalline silicon nitride nano dots.

14. The method of claim 10, wherein the tunnelling film is amorphous.

15. The method of claim 13, wherein the crystalline silicon nitride nano dots are polycrystalline.

16. The method of claim 11, wherein the crystalline silicon nitride is crystalline silicon nitride nano dots.

17. The method of claim 12, wherein the crystalline silicon nitride is crystalline silicon nitride nano dots.

18. The method of claim 16, wherein the crystalline silicon nitride nano dots are polycrystalline.

19. The method of claim 17, wherein the crystalline silicon nitride nano dots are polycrystalline.
